(19) United States
(12) Patent Application Publication
(10) Pub. No.: US 2024/0292607 A1
(43) Pub. Date: Aug. 29, 2024

(54) SELF-ALIGNED LINE CONTACTS

(71) Applicant: Micron Technology, Inc., Boise, ID (US)

(72) Inventors: Jun Ho Lee, Higashihiroshima City (JP); Byung Yoon Kim, Boise, ID (US); Sangmin Hwang, San Jose, CA (US)

(21) Appl. No.: 18/583,319

(22) Filed: Feb. 21, 2024

Related U.S. Application Data
(60) Provisional application No. 63/448,173, filed on Feb. 24, 2023.

(51) Int. Cl. H10B 12/00

(52) U.S. Cl. CPC H10B 12/488; H10B 12/02

(57) ABSTRACT

A variety of applications can include an apparatus having a device including line contacts to closely-spaced conductive signal lines structured such that a sufficient margin for shorts between a signal line and a line contact to a directly adjacent signal line is maintained even with a misalignment of the line contact. In an embodiment, formation of a memory device can include forming a line contact on and contacting an access line for an array of memory cells, using a two stage removal procedure of different removal processes. The two stage removal procedure can include removing a portion of processing layers above an insulating protective layer positioned on the access line and selectively removing the insulating protective layer, exposing a portion of the access line, without removing material of the access line. The line contact can be formed on and contacting the top exposed portion of the access line.

### PRIORITY APPLICATION

This application claims the benefit of priority to U.S. Provisional Application Ser. No. 63/448,173, filed Feb. 24, 2023, which is incorporated herein by reference in its entirety.

### FIELD OF THE DISCLOSURE

Embodiments of the disclosure relate generally to integrated circuits and, more specifically, to memory devices having self-aligned memory line contacts and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, line contacts in an integrated circuit for the electronic devices.

### BRIEF DESCRIPTION OF THE DRAWINGS

The drawings, which are not necessarily drawn to scale, illustrate generally, by way of example, but not by way of limitation, various embodiments discussed in the present document.

FIGS. 1-6 are cross-sectional representations of a process to self-align a line contact to an access line using two different removal processes to generate an opening to the access line that is filled with the line contact, according to various embodiments.

FIG. 7 is a top view of a representation of a set of access lines and associated line contacts to the access lines, according to various embodiments.

FIG. 8 is a cross-sectional representation along a direction perpendicular to the length of the access lines of FIG. 7, according to various embodiments.

FIG. 9 is a cross-sectional representation of two adjacent access lines in the z-y plane, perpendicular to the length of these access lines, that have been formed using the two etch process of FIGS. 1-6 or variation thereof, according to various embodiments.

FIG. 10 is a cross-sectional representation of another two adjacent access lines in the z-y plane, perpendicular to the length of these access lines, that have been formed using the two etch process of FIGS. 1-6 or variation thereof, according to various embodiments.

FIG. 11 shows a flow diagram of features of a method of forming a memory device, according to various embodiments.

FIG. 12 is a flow diagram of features of an example method of forming a memory device, according to various embodiments.

FIG. 13 is a schematic of an embodiment of an example dynamic random-access memory device that can include an architecture having a memory array with self-aligned contacts, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

As design rules for fabrication of integrated circuits tend to shrinkage of distances between conductive components, associated margins for shorts between the conductive components decrease. For example, a memory device includes memory lines and line contacts to the memory lines, where line contacts to memory lines and directly adjacent memory lines should be electrically isolated from each other. Misalignment of the line contacts can reduce the desired isolation. Memory lines can be access lines (e.g. word lines) or digit lines (e.g. bit lines) and can be composed of one or more metals. A margin for a short can be associated with the distance between a memory line and directly adjacent memory line. Other margins for shorts can be associated with the distance between a memory line and a line contact, where the line contact is a line contact to another memory line directly adjacent the memory line. For example, with design rules tending to shrinkage, a margin for a short between an access line and a line contact to a directly adjacent access line is becoming smaller. If there is misalignment in the formation of line contacts to access lines, the margin for a short is significantly smaller, which is an unwanted occurrence. In conventional approaches, there is a limitation to the ability to control misalignment and it is typically difficult to shrink the critical dimension (CD) of the bottom of the line contact to an access line.

In various embodiments, a combination of two or more different removal processes are implemented in forming a line contact to a memory line. The implementation can include stopping a first removal process at the top of a protective layer on and contacting the memory line and removing the protective layer exposing the memory line using a second removal process that stops at the top of the access line. The first removal process can be a dry etch and the second removal process can be a selective removal process. The selective removal process can be a selective wet etch. The memory line can be a conductive access line and the protective layer on and contacting the access line can be a insulative silicon nitride layer. Before applying the second removal process, an insulating spacer can be formed in an opening to the protective layer created by the first removal process. The insulating spacer can be an oxide spacer.

The multiple removal process, using different processes, in forming a line contact to a memory line can increase the margin for a short between a memory line and a line contact to a directly adjacent memory line. For example, applying a dry etch followed by applying a wet etch can the increase the margin for a short between an access line and a line contact to a directly adjacent access line. This combined removal process can provide immunity to a bad misalignment. This immunity in the formation of the line contact can make the line contact self-aligned.

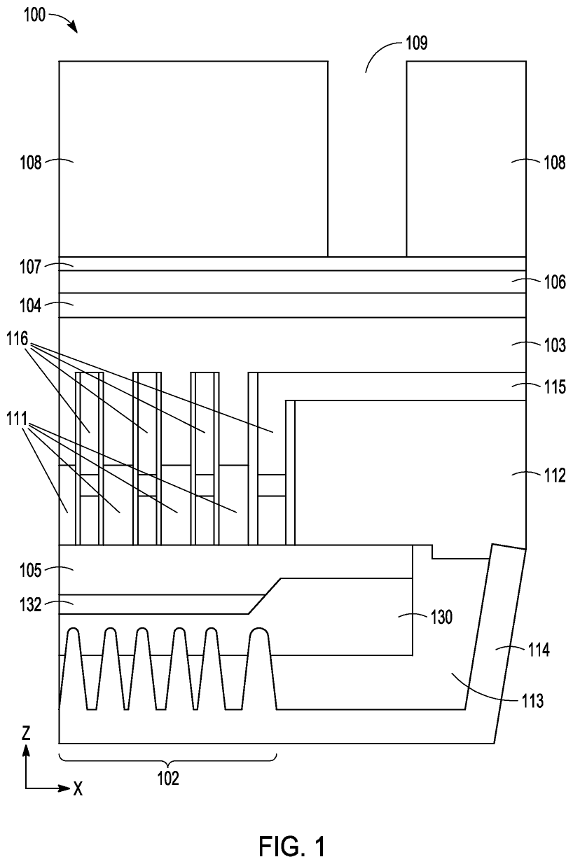

FIGS. 1-6 are cross-sectional representations of a process to self-align a line contact to an access line using two different removal processes to generate an opening to the access line that is filled with the line contact. FIG. 1 shows a structure 100 after memory cells 102 have been formed. Memory cells 102 can be, but are not limited to, silicon-based memory cells formed in a silicon-based region 114. An access line 130 has been formed coupled to memory cells 102 along the horizontal x-direction, while another access line 132 has been formed. Access lines 130 and 132 can be implemented by polysilicon or one or more metals. Above the access line 130 in the z-direction is a protective region 105 along the horizontal x-direction. Protective region 105 can include one or more gap fill materials such as, but not limited to, an oxide or silicon nitride. In this cross-sectional view, above protective region 105, digit line masks 116 and conductive contacts 111 have been formed. Digit line masks 116 can include one or more of silicon nitride or carbon and conductive contacts 111 can include polysilicon or one or more metals. Gap fill regions 113 and 112 have been formed around these regions. Gap fill regions 113 and 112 can include oxide, silicon nitride, or similar materials. Above gap fill region 112, an upper protective region 115 has been formed, which can include an oxide or silicon nitride. The composition of upper protective region 115 can be the same as the composition of protective region 105. A masking region 103 has been formed over upper protective region 115, digit line masks 116, and conductive contacts 111. Masking region 103 can include one or more of an oxide or carbon.

Processing layers have been formed above masking region 103, forming a mask stack. The processing layers can include a dielectric anti-reflective coating (DARC) layer 104, a underlayer (UL) 106, a hard mask (HM) 107, and a resist layer 108. An opening 109 has been formed in resist layer 108 to the top of the hard mask 107.

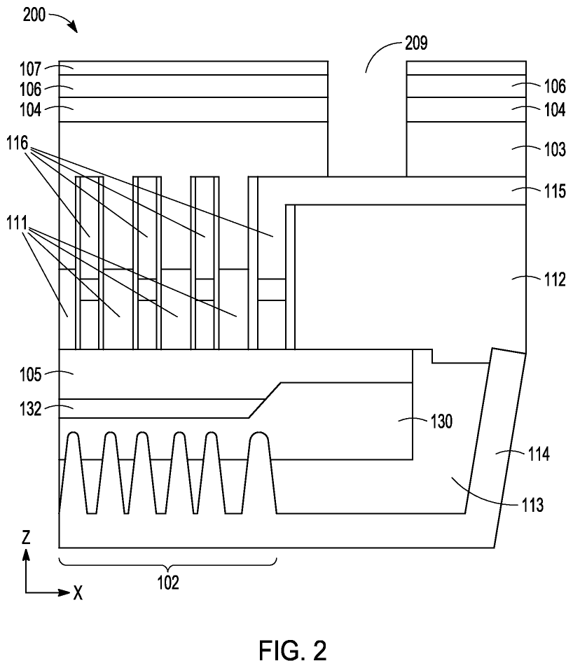

FIG. 2 shows a cross-sectional view of a structure 200 after processing structure 100 of FIG. 1. A multi-step dry etch has been performed through opening 109. Portions of HM 107, UL 106, DARC 104, and masking region 103 have been removed, stopping at the top of upper protective 115, forming opening 209.

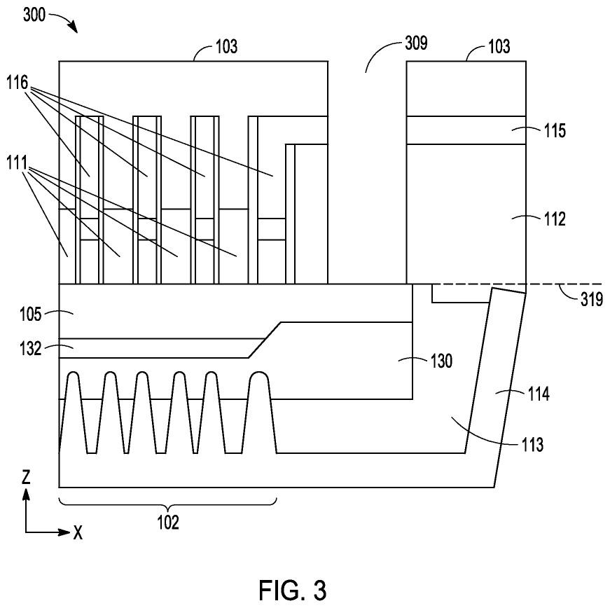

FIG. 3 shows a cross-sectional view of a structure 300 after processing structure 200 of FIG. 2. A multi-step dry etch has been performed to remove portions of upper protective layer 115 and gap fill regions 112, stopping at a level 319 that is the top of protective region 105 such as a top of a silicon nitride protective region. The dry etch forms opening 309. The control of the dry etch to level 319 can be controlled by end point detection.

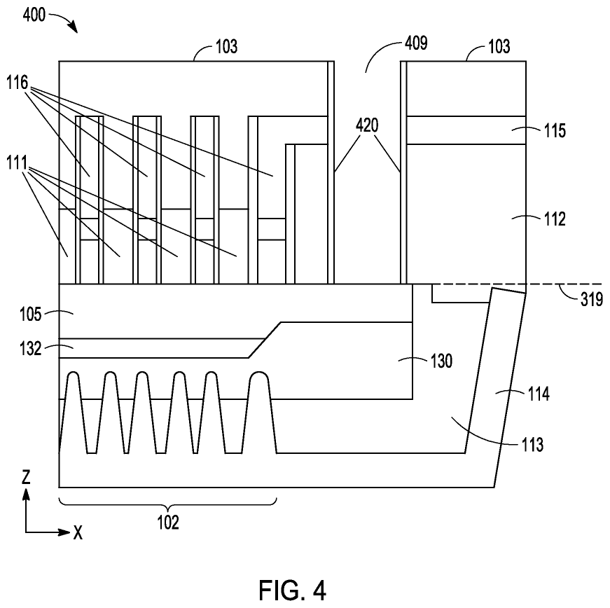

FIG. 4 shows a cross-sectional view of a structure 400 after processing structure 300 of FIG. 3. A spacer oxide 420 had been formed in opening 309 of structure 300 of FIG. 3. Spacer oxide 420 has been formed on the vertical surfaces of protective layer 115 and gap fill regions 112 of opening 309 from the top of masking region 103 to the top of protective region 105 at level 319. Spacer oxide 420 has been etched back, forming opening 409. The etch back has been formed to provide a size of opening 409 appropriate to subsequently form a line contact to access line 130.

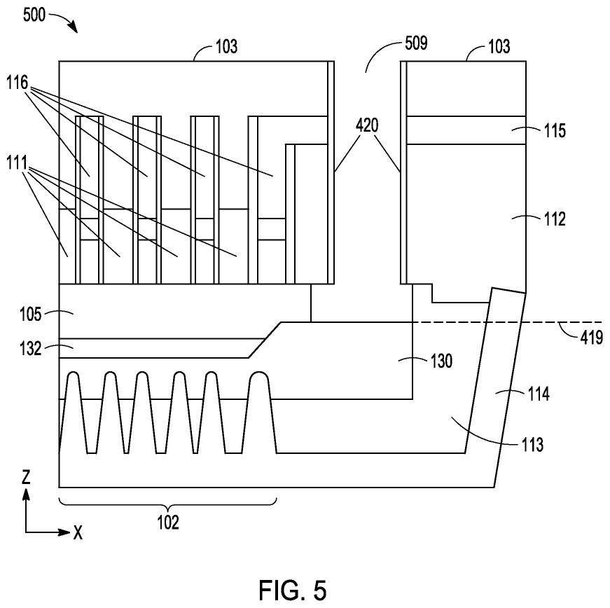

FIG. 5 shows a cross-sectional view of a structure 500 after processing structure 400 of FIG. 4. Protective region 105 has been removed by performing a selective wet etch through opening 409. The use of the selective wet etch allows removal of protective region 105 without removal of material of access line 130, that is, a formed opening 509 stops at the top of access line 130 at level 419. With protective region 105 being a silicon nitride, a wet chemical etch can be applied using phosphoric acid (H₃PO₄). Other selective etchants can be used to remove protective region 105 to the top of access line 130. The selective wet etch can also maintain oxide spacer 420 in opening 509.

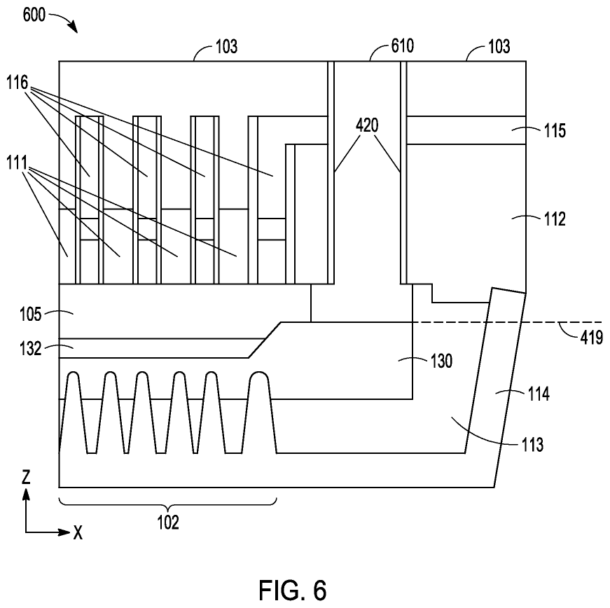

FIG. 6 shows a cross-sectional view of a structure 600 after processing structure 500 of FIG. 5. A line contact 610 has been formed in opening 509 of structure 500 of FIG. 5. Line contact 610 has been formed extending from the top of access line 130 to the top of masking region 103. Line contact 610 has been formed by filling opening 509. Line contact 610 can include one or more of tungsten, ruthenium, tungsten nitride, titanium, tungsten silicide, polysilicon, combinations thereof, or other conductive materials appropriate for the functionality of line contact 610 in the memory device being formed.

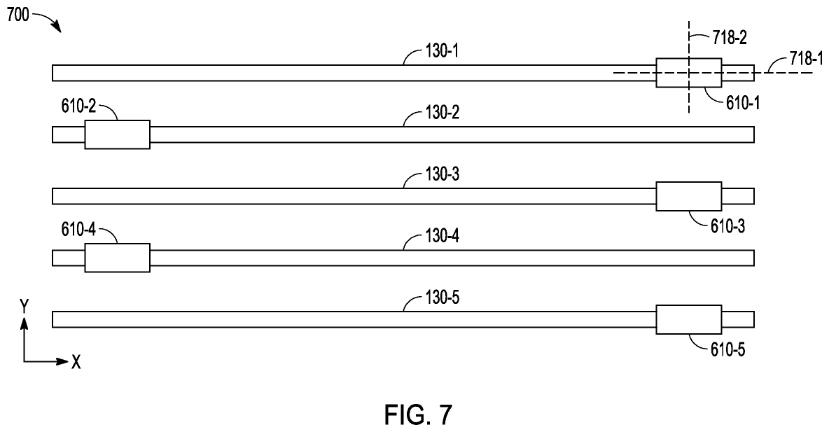

FIG. 7 is a top view of a representation 700 of a set of access lines and associated line contacts to the access lines. The set includes access line 130-1 with line contact 610-1 on and extending vertically (in the z-direction, not shown) from access line 130-1. The directional line 718-1 corresponds to the direction along access line 130 in FIGS. 1-6. Directional line 718-2 is perpendicular to directional line 718-1. The set includes access line 130-2 with line contact 610-2 on and extending vertically, in the z-direction, from access line 130-2. The set includes access line 130-3 with line contact 610-3 on and extending vertically, in the z-direction, from access line 130-3. The set includes access line 130-4 with line contact 610-4 on and extending vertically, in the z-direction, from access line 130-4. The set includes access line 130-5 with line contact 610-5 on and extending vertically, in the z-direction, from access line 130-5. Though representation 700 shows five access lines and five line contacts, a memory device can have significantly more than or fewer than five access lines and five line contacts.

In a conventional process, when material of the access line is removed by a dry etch to provide the location of the line contact, the end of the line contact can be at a level below the top level of an adjacent access line. As a result, the minimum distance between such a line contact and the adjacent access line is smaller than the minimum distance between the adjacent access line and the access line on which the line contact is positioned, which decreases the margin for a short. In contrast, in the process of FIGS. 1-6, using a selective etch to provide an opening to deposit a line contact to an access line can result in the line contact ending at the top level of the access line, that is, the selective etch does remove material of the access line. As a result, the minimum distance between such a line contact and the adjacent access line is larger than the minimum distance between the adjacent access line and the access line on which the line contact is positioned.

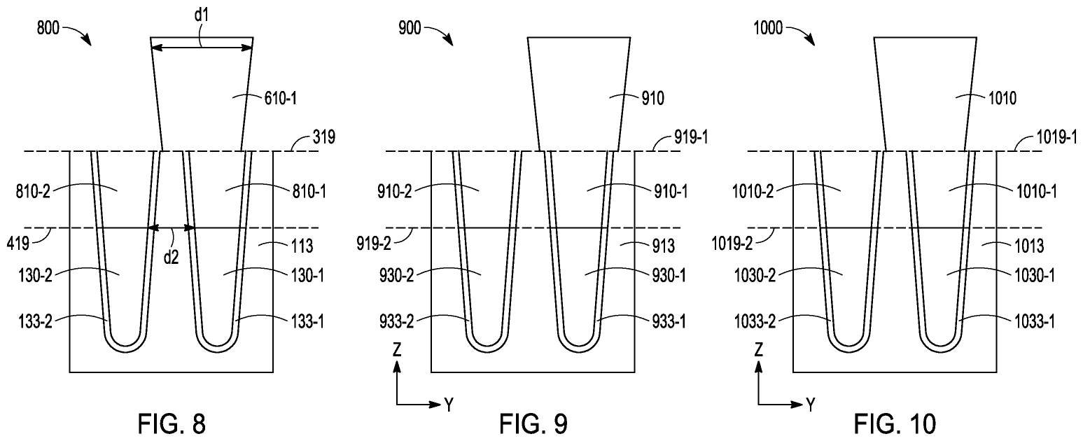

FIG. 8 is a cross-sectional representation 800 along direction 718-2 of FIG. 7. In this view, contact 610-1 to access line 130-1 is shown above level 319, which was the level of the etch stop for the dry etch in forming the structure of representation 800. A region 810-1 includes the metal of contact 610-1 filling the region formed by wet etching from level 319 to level 419 at the top of access line 130-1. The wet etch is a selective etch to prevent region 810-1 from expanding laterally towards the boundaries of line contact 610-1 formed by dry eteching. A gate oxide 133-1 for memory cells 102 is on access line 130-1 in gap fill region 113. Also shown is directly adjacent access line 130-2 contacting a gate oxide 133-2. A region 810-2 includes metal of contact 610-2 of FIG. 7 filling the region formed by wet etching from level 319 to level 419 at the top of access line 130-2. Access line 130-1 and 130-2 are separated by a minimum distance d2. Line contact 610-1 above access 130-1 has a width d2, where width d1 is significantly larger than distance d2.

FIG. 9 is a cross-sectional representation 900 of two adjacent access lines 930-1 and 930-2, perpendicular to the length of these access lines (in the x-direction, not shown), that have been formed using the two etch process of FIGS. 1-6 or variation thereof. In this view, line contact 910 to access line 930-1 is shown above level 919-1, which was the level of the etch stop for a dry etch in forming the structure of representation 900. A region 910-1 includes the metal of contact 910 filling a region formed by wet etching from level 919-1 to level 919-2 at the top of access line 930-1. The wet etch is a selective etch to prevent region 810-1 from expanding laterally to the boundaries of line contact 910 formed using dry eteching. A gate oxide 933-1 for memory cells is on access line 930-1 in gap fill region 913. Also shown is directly adjacent access line 930-2 contacting a gate oxide 933-2. A region 910-2 includes metal of a contact, for access line 930-2, filling a region formed by wet etching from level 919-1 to to level 919-2 at the top of access line 930-2.

FIG. 10 is a cross-sectional representation 1000 of two adjacent access lines 1030-1 and 1030-2, perpendicular to the length of these access lines (in the x-direction, not shown), that have been formed using the two etch process of FIGS. 1-6 or variation thereof. In this view, line contact 1010 to access line 1030-1 is shown above level 1019-1, which was the level of the etch stop for a dry etch in forming the structure of representation 1000. A region 1010-1 includes the metal of contact 1010 filling a region formed by wet etching from level 1019-1 to level 1019-2 at the top of access line 1030-1. The wet etch is a selective etch to prevent region 1010-1 from expanding laterally towards the boundaries of line contact 1010 formed using dry eteching. A gate oxide 1033-1 for memory cells is on access line 1030-1 in gap fill region 1013. Also shown is directly adjacent access line 1030-2 contacting a gate oxide 1033-2. A region 1010-2 includes metal of a contact, for access line 1030-2, filling a region formed by wet etching from level 1019-1 to to level 1019-2 at the top of access line 130-2. In contrast to line contact 910 of FIG. 9, line contact 1010 has been formed with a registration out of specification, shifted horizontally by more than zero nanometers. The process of FIGS. 1-6, which stops a dry etch, forms an oxide spacer, and uses a selective wet etch to form line contact 1010, allows line contact 1010 to be out specification at the top portion of line contact 1010, without metal of region 1010-1, extending from line contact 1010, spreading laterally from the top level of access lines 1030-1. This process addresses the issue of decreasing margins for shorts associated with conventional processing.

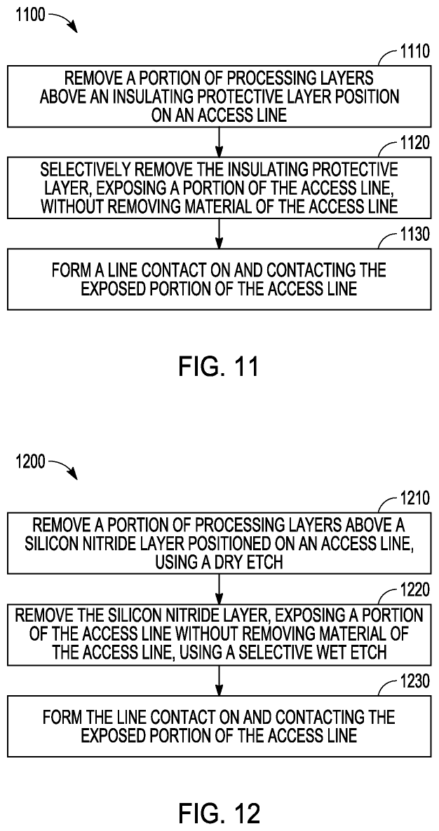

FIG. 11 shows a flow diagram of features of a method 1100 of forming a memory device. Method 1100 can include forming a line contact on and contacting an access line for an array of memory cells of the memory device. The formation of the line contact can be accomplished using a two stage removal procedure having different removal processes. At 1110, a portion of processing layers can be removed, where the processing layers are located above an insulating protective layer positioned on the access line. At 1120, the insulating protective layer can be selectively removed, exposing a portion of the access line, without removing material of the access line. Selectively removing the insulating protective layer without removing the material of the access line can include using one or more chemicals for removal to which the material of the access line is resistant. At 1130, the line contact is formed on and contacting the exposed portion of the access line.

Variations of method 1100 or methods similar to method 1100 can include a number of different embodiments that may be combined depending on the application of such methods and/or the architecture of systems including a memory device in which such methods are implemented. Such methods can include the insulating protective layer containing silicon nitride. Variations can include the processing layers containing a hard mask, an underlayer coating, a dielectric anti-reflective coating layer, a carbon layer, a silicon nitride layer, and an oxide layer on the insulating protective layer.

Variations of method 1100 or methods similar to method 1100 can include forming a spacer oxide in an opening formed by removing the portion of processing layers above the insulating protective layer. The line contact can be formed on the spacer oxide during the formation of the line contact on and contacting the exposed portion of the access line. Variations can include removing the portion of processing layers above the insulating protective layer with the stopping of the removal on the insulating protective layer. Stopping the removal on the insulating protective layer can include, but is not limited to, using an end point detection to stop the removal.

In various embodiments, a memory device can include access lines to an array of memory cells and line contacts to the access lines, which line contacts can be formed to increase the margin for an electrical short associated with distance of an access line to a line contact of a directly adjacent access line and provide relative immunity to misalignments of the line contacts. For each pair of directly adjacent access lines and the set of line contacts, a first access line of a pair contacts a first line contact of the line contacts, where the first line contact is self-aligned such that a minimum distance between the first access line and a second access line of the pair is less than a minimum distance between the second access line and the first line contact.

Variations of such a memory device and its features, as taught herein, can include a number of different embodiments and features that can be combined depending on the application of such memory devices, the format of such memory devices, and/or the architecture in which such memory devices are implemented. Variations of such memory devices can include the line contacts to assigned access lines terminating at a level above a top of the access lines outside horizontal extents of the assigned access lines. Variations can include the line contacts containing one or more of tungsten, ruthenium, tungsten nitride, titanium, tungsten silicide, polysilicon, or combinations thereof.

Variations of such a memory device and its features can include the access lines containing one or more of polysilicon or a metal. Variations can include material of the access lines being selectively resistant to etchants for removing material layers positioned on and contacting the access lines during processing of the line contacts to couple to the access lines. Variations can include material of the access lines being selectively resistant to etching by phosphoric acid.

Methods of forming such memory devices is not limited to line contacts to access lines to increase the margin for an electrical short associated with distance of an access line to a line contact of a directly adjacent access line and provide relative immunity to mis-alignments of the line contacts. The techniques, taught herein, can be extended to signal lines in other memory devices or in other electronic devices in an integrated circuit chip. For example, a method of forming a memory device can include forming a line contact on and contacting a memory cell line for an array of memory cells of the memory device, where a memory cell line is an access line or a digit line. The formation of the line contact can be accomplished using a two stage removal procedure having different removal processes. In such a method, a portion of processing layers above an insulating protective layer positioned on the memory cell line is removed. The insulating protective layer is selectively removed, exposing a portion of the memory cell line, without removing material of the memory cell line. Selectively removing the insulating protective layer without removing the material of the memory cell line can include using one or more chemicals for removal that are resistant by the material of the memory cell line for removal. The line contact is formed on and contacting the exposed portion of the memory cell line.

Variations of such a method can include a number of different embodiments that may be combined depending on the application of such methods and/or the architecture of systems including a memory device in which such methods are implemented. Such methods can include the insulating protective layer containing silicon nitride. Variations can include the processing layers containing a hard mask, an underlayer coating, a dielectric anti-reflective coating layer, a carbon layer, a silicon nitride layer, and an oxide layer on the insulating protective layer.

Variations of such a method can include forming a spacer oxide in an opening formed by removing the portion of processing layers above the insulating protective layer. The line contact can be formed on the spacer oxide during the formation of the line contact on and contacting the exposed portion of the memory cell line. Variations can include removing the portion of processing layers above the insulating protective layer with the stopping of the removal on the insulating protective layer. Stopping the removal on the insulating protective layer can include, but is not limited to, using an end point detection to stop the removal.

In various embodiments, a memory device can include memory cell lines to an array of memory cells, where a memory cell line is an access line or a digit line, and can include line contacts to the memory cell lines. For each pair of directly adjacent memory cell lines, a first memory cell line of a pair contacts a first line contact of the set of line contacts, where the first line contact is self-aligned such that a minimum distance between the first memory cell line and a second memory cell line of the pair is less than a minimum distance between the second memory line and the first line contact.

Variations of such a memory device and its features, as taught herein, can include a number of different embodiments and features that can be combined depending on the application of such memory devices, the format of such memory devices, and/or the architecture in which such memory devices are implemented. Variations of such memory devices can include the line contacts to assigned memory cell lines terminating at a level above a top of the memory cell lines outside horizontal extents of the assigned memory cell lines. Variations can include the line contacts containing one or more of tungsten, ruthenium, tungsten nitride, titanium, tungsten silicide, polysilicon, or combinations thereof.

Variations of such a memory device and its features can include the memory cell lines containing one or more of polysilicon or a metal. Variations can include material of the memory cell lines being selectively resistant to etchants for removing material layers positioned on and contacting the memory cell lines during processing of the line contacts to couple to the memory cell lines. Variations can include material of the memory cell lines being selectively resistant to etching by phosphoric acid.

FIG. 12 shows a flow diagram of features of a method 1200 of forming a memory device. Method 12 can include forming a line contact on and contacting an access line for an array of memory cells of the memory device. The formation of the line contact can be accomplished using a dry etch and wet etch procedure. At 1210, a portion of processing layers above a silicon nitride layer positioned on the access line is removed using a dry etch. At 1220, the silicon nitride layer is removed using a selective wet etch, exposing a portion of the access line without removing material of the access line. At 1230, the line contact is formed on and contacting the exposed portion of the access line.

Variations of method 1200 or methods similar to method 1200 can include a number of different embodiments that may be combined depending on the application of such methods and/or the architecture of systems including a memory device in which such methods are implemented. Such methods can include depositing an oxide spacer in an opening formed by the dry etch prior to removing the silicon nitride layer using the selective wet etch. Variations can include removing the silicon nitride layer using the selective wet etch that includes using a wet phosphoric acid etchant.

Variations of method 1200 or methods similar to method 1200 can include removing the portion of processing layers above the silicon nitride layer positioned on the access line by stopping the dry etch at a top of the silicon nitride layer. Variations can include removing the portion of processing layers above a silicon nitride layer positioned on the access line by performing a multi-step dry etch. Variations can include performing the multi-step dry etch, removing one or more of the processing layers that are positioned above a top silicon nitride layer on and contacting an oxide region that is on the silicon nitride layer positioned on the access line. Variations can include performing an additional multi-step dry etch, removing the top silicon nitride layer and the oxide region, and stopping the additional multi-step dry etch on the silicon nitride layer positioned on the access line.

In various embodiments, a method of forming a memory device can include forming a line contact on and contacting a memory cell line for an array of memory cells of the memory device, where a memory cell line is an access line or a digit line and the formation of the line contact can be accomplished using a dry etch and wet etch procedure. In such a method, a portion of processing layers above a silicon nitride layer positioned on the memory cell line can be removed using a dry etch. The silicon nitride layer can be removed using a selective wet etch, exposing a portion of the memory cell line without removing material of the memory cell line. The line contact can be formed on and contacting the exposed portion of the memory cell line.

Variations of such a method can include a number of different embodiments that may be combined depending on the application of such methods and/or the architecture of systems including a memory device in which such methods are implemented. Such methods can include depositing an oxide spacer in an opening formed by the dry etch prior to removing the silicon nitride layer using the selective wet etch. Variations can include removing the silicon nitride layer using the selective wet etch that includes using a wet phosphoric acid etchant.

Variations of such a method can include removing the portion of processing layers above the silicon nitride layer positioned on the memory cell line by stopping the dry etch at a top of the silicon nitride layer. Variations can include removing the portion of processing layers above a silicon nitride layer positioned on the memory cell line by performing a multi-step dry etch. Variations can include performing the multi-step dry etch, removing one or more of the processing layers that are positioned above a top silicon nitride layer on and contacting an oxide region that is on the silicon nitride layer positioned on the memory cell line. Variations can include performing an additional multi-step dry etch, removing the top silicon nitride layer and the oxide region, and stopping the additional multi-step dry etch on the silicon nitride layer positioned on the memory cell line.

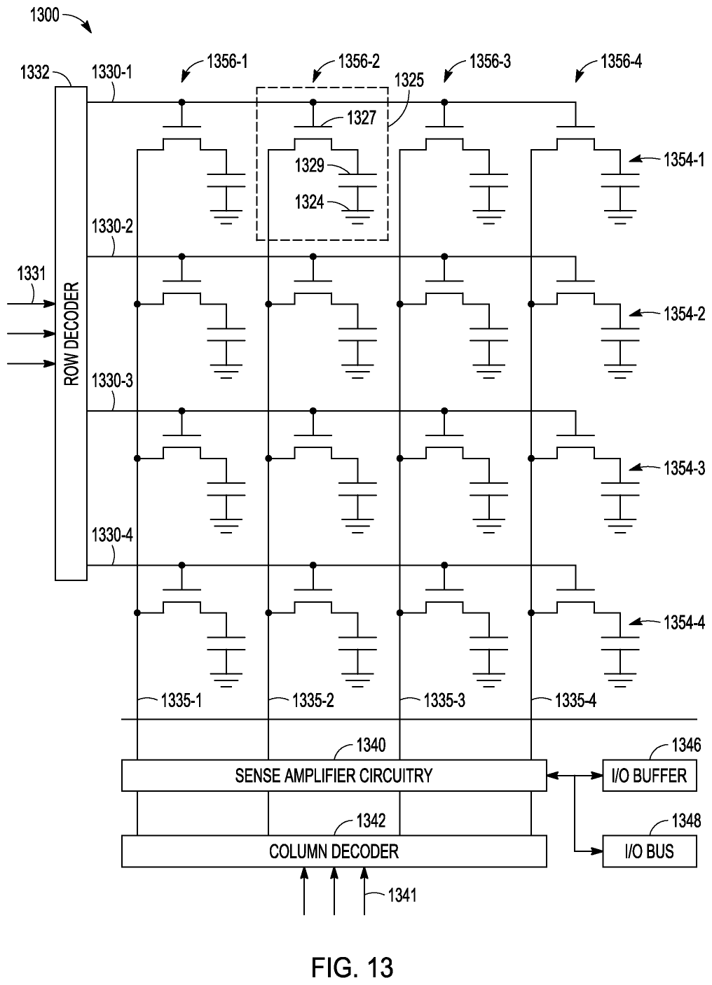

FIG. 13 is a schematic of an embodiment of an example DRAM device 1300 that can include an architecture having a memory array region and periphery circuits to the memory array, in which memory lines, such as access lines, can be formed using the process of FIGS. 1-6 or variations thereof to form line contacts on memory lines as discussed herein with respect to FIGS. 1-12. DRAM device 1300 can include an array of memory cells 1325 (only one being labeled in FIG. 13 for case of presentation) arranged in rows 1354-1, 1354-2, 1354-3, and 1354-4 and columns 1356-1, 1356-2, 1356-3, and 1356-4. For simplicity and ease of discussion, the array is shown in only two dimensions, but the array can be extended into the third dimension. Further, while only four rows 1354-1, 1354-2, 1354-3, and 1354-4 and four columns 1356-1, 1356-2, 1356-3, and 1356-4 of four memory cells are illustrated, DRAM devices, like DRAM device 1300, can have significantly more memory cells 1325 (e.g., tens, hundreds, or thousands of memory cells) per row or per column.

Each memory cell 1325 can include a single transistor 1327 and a single capacitor 1329, which is commonly referred to as a 1T1C (one-transistor-one capacitor cell). One plate of capacitor 1329, which can be termed the “node plate,” is connected to the drain terminal of transistor 1327, whereas the other plate of the capacitor 1329 is connected to ground 1324 or other reference node. Each capacitor 1329 within the array of 1T1C memory cells 1325 typically serves to store one bit of data, and the respective transistor 1327 serves as an access device to write to or read from storage capacitor 1329.

The transistor gate terminals within each row of rows 1354-1, 1354-2, 1354-3, and 1354-4 are portions of respective access lines 1330-1, 1330-2, 1330-3, and 1330-4 (alternatively referred to as “word lines”), and the transistor source terminals within each of columns 1356-1, 1356-2, 1356-3, and 1356-4 are electrically connected to respective digit lines 1335-1, 1335-2, 1335-3, and 1335-4 (alternatively referred to as “bit lines”). A row decoder 1332 can selectively drive the individual access lines 1330-1, 1330-2, 1330-3, and 1330-4, responsive to row address signals 1331 input to row decoder 1332. Driving a given access line at a high voltage causes the access transistors within the respective row to conduct, thereby connecting the storage capacitors within the row to the respective data lines, such that charge can be transferred between the data lines and the storage capacitors for read or write operations. Both read and write operations can be performed via sense amplifier (SA) circuitry 1340, which can transfer bit values between the memory cells 1325 of the selected row of the rows 1354-1, 1354-2, 1354-3, and 1354-4 and input/output buffers 1346 (for write/read operations) or external input/output data buses 1348.

A column decoder 1342 responsive to column address signals 1341 can select which of the memory cells 1325 within the selected row is read out or written to. Alternatively, for read operations, the storage capacitors 1329 within the selected row can be read out simultaneously and latched, and the column decoder 1342 can then select which latch bits to connect to the output data bus 1348. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 1300 can be implemented as an integrated circuit within a package that includes pins for receiving supply voltages (e.g., to provide the source and gate voltages for the transistors 1327) and signals (including data, address, and control signals). FIG. 13 depicts DRAM device 1300 in simplified form to illustrate basic structural components, omitting many details of the memory cells 1325 and associated access lines 1330-1, 1330-2, 1330-3, and 1330-4 and digit lines 1335-1, 1335-2, 1335-3, and 1335-4 as well as the peripheral circuitry. For example, in addition to the row decoder 1332 and column decoder 1342, SA circuitry 1340, and buffers 1346, DRAM device 1300 can include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) DRAM arrays, the rows 1354-1, 1354-2, 1354-3, and 1354-4 and columns 1356-1, 1356-2, 1356-3, and 1356-4 of memory cells 1325 are arranged along a single horizontal plane (i.e., a plane parallel to the layers) of the semiconductor substrate, e.g., in a rectangular lattice with mutually perpendicular horizontal access lines 1330-1, 1330-2, 1330-3, and 1330-4 and digit lines 1335-1, 1335-2, 1335-3, and 1335-4. In 3D DRAM arrays, the memory cells 1325 are arranged in a 3D lattice that encompasses multiple vertically stacked horizontal planes corresponding to multiple device tiers of a multi-tier substrate assembly, with each device tier including multiple parallel rows of memory cells 1325 whose transistor gate terminals are connected by horizontal access lines such as access lines 1330-1, 1330-2, 1330-3, and 1330-4. (A “device tier,” as used herein, can include multiple layers (or levels) of materials, but forms the components of memory devices of a single horizontal tier of memory cells.) Digit lines 1335-1, 1335-2, 1335-3, and 1335-4 extend vertically through all or at least a vertical portion of the multi-tier structure, and each of the digit lines 1335-1, 1335-2, 1335-3, and 1335-4 connects to the transistor source terminals of respective vertical columns 1356-1, 1356-2, 1356-3, and 1356-4 of associated memory cells 1325 at the multiple device tiers. This 3D configuration of memory cells enables further increases in bit density compared with 2D arrays.

Though FIG. 13 provides an example of DRAM 1300 that can include line contacts to memory lines as discussed with respect to FIGS. 1-12, other integrated circuits (ICs), including but not limited to other memory devices, can implement similar structures having line contacts to conductive signal lines that can be used in a variety of electronic devices. Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Such electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices. These electronic devices provide examples of structures that can include asymmetric transistor devices within the electronic devices.

The following examples are example embodiments of methods, devices, and systems, in accordance with the teachings herein.

An example memory device 1 can comprise memory cell lines to an array of memory cells, a memory cell line being an access line or a digit line; and line contacts to the memory cell lines such that, for each pair of directly adjacent memory cell lines, a first memory cell line of a pair contacts a first line contact of the line contacts, the first line contact being self-aligned such that a minimum distance between the first memory cell line and a second memory cell line of the pair is less than a minimum distance between the second memory line and the first line contact.

An example memory device 2 can include features of example memory device 1 and can include the line contacts to assigned memory cell lines terminating at a level above a top of the memory cell lines outside horizontal extents of the assigned memory cell lines.

An example memory device 3 can include features of any of the preceding example memory devices and can include the line contacts including one or more of tungsten, ruthenium, tungsten nitride, titanium, tungsten silicide, polysilicon, or combinations thereof.

An example memory device 4 can include features of any of the preceding example memory devices and can include the memory cell lines including one or more of polysilicon or a metal.

An example memory device 5 can include features of any of the preceding example memory devices and can include material of the memory cell lines being selectively resistant to etchants for removing material layers positioned on and contacting the memory cell lines during processing of the line contacts to couple to the memory cell lines.

An example memory device 6 can include features of example memory device 5 and any of the preceding example memory devices and can include material of the access lines being selectively resistant to etching by phosphoric acid.

In an example memory device 7, any of the memory devices of example memory devices 1 to 6 may include memory devices incorporated into an electronic apparatus further comprising a host processor and a communication bus extending between the host processor and the memory device.

In an example memory device 8, any of the memory devices of example memory devices 1 to 7 may be modified to include any structure presented in another of example memory device 1 to 7.

In an example memory device 9, any apparatus associated with the memory devices of example memory devices 1 to 8 may further include a machine-readable storage device configured to store instructions as a physical state, wherein the instructions may be used to perform one or more operations of the apparatus.

In an example memory device 10, any of the memory devices of example memory devices 1 to 9 may be formed or operated in accordance with any of the below example methods 1 to 40.

An example memory device 11 can comprise access lines to an array of memory cells; and line contacts to the access lines such that, for each pair of directly adjacent access lines, a first access line of a pair contacts a first line contact of the line contacts, the first line contact being self-aligned such that a minimum distance between the first access line and a second access line of the pair is less than a minimum distance between the second access line and the first line contact.

An example memory device 12 can include features of example memory device 11 and can include the line contacts to assigned access lines terminate at a level above a top of the access lines outside horizontal extents of the assigned access lines.

An example memory device 13 can include features of any features of the preceding example memory devices 11 to 12 and can include the line contacts including one or more of tungsten, ruthenium, tungsten nitride, titanium, tungsten silicide, polysilicon, or combinations thereof.

An example memory device 14 can include features of any of the preceding example memory devices 11 to 13 and can include the access lines including one or more of polysilicon or a metal.

An example memory device 15 can include features of any of the preceding example memory devices 11 to 14 and can include material of the access lines being selectively resistant to etchants for removing material layers positioned on and contacting the access lines during processing of the line contacts to couple to the access lines.

An example memory device 16 can include features of example memory device 15 and any of the preceding example memory devices 11 to 14 and can include material of the access lines being selectively resistant to etching by phosphoric acid.

In an example memory device 17, any of the memory devices of example memory devices 11 to 16 may include the memory devices incorporated into an electronic apparatus further comprising a host processor and a communication bus extending between the host processor and the memory device.

In an example memory device 18, any of the memory devices of example memory devices 11 to 17 may be modified to include any structure presented in another of example memory device 11 to 17.

In an example memory device 19, any apparatus associated with the memory devices of example memory devices 11 to 18 may further include a machine-readable storage device configured to store instructions as a physical state, wherein the instructions may be used to perform one or more operations of the apparatus.

In an example memory device 20, any of the memory devices of example memory devices 11 to 19 may be formed or operated in accordance with any of the below example methods 1 to 40.

An example method 1 of forming a memory device can comprise forming a line contact on and contacting a memory cell line for an array of memory cells, the memory cell line being an access line or a digit line, using a two stage removal procedure of different removal processes including: removing a portion of processing layers above an insulating protective layer positioned on the memory cell line; selectively removing the insulating protective layer, exposing a portion of the memory cell line, without removing material of the memory cell line; and forming the line contact on and contacting the exposed portion of the memory cell line.

An example method 2 of forming a memory device can include features of example method 1 of forming a memory device and can include the insulating protective layer including silicon nitride.

An example method 3 of forming a memory device can include features of any of the preceding example methods of forming a memory device and can include the processing layers including a hard mask, an underlayer coating, a dielectric anti-reflective coating layer, a carbon layer, a silicon nitride layer, and an oxide layer on the insulating protective layer.

An example method 4 of forming a memory device can include features of any of the preceding example methods of forming a memory device and can include forming a spacer oxide in an opening formed by removing the portion of processing layers above the insulating protective layer; and forming the line contact on the spacer oxide during the forming of the line contact on and contacting the exposed portion of the memory cell line.

An example method 5 of forming a memory device can include features of any of the preceding example methods of forming a memory device and can include removing the portion of processing layers above the insulating protective layer to include stopping the removal on the insulating protective layer.

An example method 6 of forming a memory device can include features of example method 5 of forming a memory device and any of the preceding example methods of forming a memory device and can include stopping the removal on the insulating protective layer to include using an end point detection to stop the removal.

An example method 7 of forming a memory device can include features of any of the preceding example methods of forming a memory device and can include selectively removing the insulating protective layer without removing the material of the memory cell line to include using one or more chemicals for removal that are resistant by the material of the memory cell line for removal.

In an example method 8 of forming a memory device, any of the example methods 1 to 7 of forming a memory device may be performed in forming an electronic apparatus further comprising a host processor and a communication bus extending between the host processor and the memory device.

In an example method 9 of forming a memory device, any of the example methods 1 to 8 of forming a memory device may be modified to include operations set forth in any other of example methods 1 to 8 of forming a memory device.

In an example method 10 of forming a memory device, any of the example methods 1 to 9 of forming a memory device may be implemented at least in part through use of instructions stored as a physical state in one or more machine-readable storage devices.

An example method 11 of forming a memory device can include features of any of the preceding example methods 1 to 10 of forming a memory device and can include performing functions associated with any features of example memory devices 1 to 10 and example memory devices 11 to 20.

An example method 12 of forming a memory device can comprise forming a line contact on and contacting an access line for an array of memory cells, using a two stage removal procedure of different removal processes including: removing a portion of processing layers above an insulating protective layer positioned on the access line; selectively removing the insulating protective layer, exposing a portion of the access line, without removing material of the access line; and forming the line contact on and contacting the exposed portion of the access line.

An example method 13 of forming a memory device can include features of example method 12 of forming a memory device and can include the insulating protective layer including silicon nitride.

An example method 14 of forming a memory device can include features of any of the preceding example methods 12-13 of forming a memory device and can include the processing layers including a hard mask, an underlayer coating, a dielectric anti-reflective coating layer, a carbon layer, a silicon nitride layer, and an oxide layer on the insulating protective layer.

An example method 15 of forming a memory device can include features of any of the preceding example methods 12-14 of forming a memory device and can include forming a spacer oxide in an opening formed by removing the portion of processing layers above the insulating protective layer; and forming the line contact on the spacer oxide during the forming of the line contact on and contacting the exposed portion of the access line.

An example method 16 of forming a memory device can include features of any of the preceding example methods 12-15 of forming a memory device and can include removing the portion of processing layers above the insulating protective layer to include stopping the removal on the insulating protective layer.

An example method 17 of forming a memory device can include features of any of the preceding example methods 12-16 of forming a memory device and can include stopping the removal on the insulating protective layer to include using an end point detection to stop the removal.

An example method 18 of forming a memory device can include features of example method 17 of forming a memory device and any of the preceding example methods 12-16 of forming a memory device and can include selectively removing the insulating protective layer without removing the material of the access line to include using one or more chemicals for removal that are resistant by the material of the access line for removal.

In an example method 19 of forming a memory device, any of the example methods 12 to 18 of forming a memory device may be performed in forming an electronic apparatus further comprising a host processor and a communication bus extending between the host processor and the memory device.

In an example method 20 of forming a memory device, any of the example methods 12 to 19 of forming a memory device may be modified to include operations set forth in any other of example methods 12 to 19 of forming a memory device.

In an example method 21 of forming a memory device, any of the example methods 12 to 20 of forming a memory device may be implemented at least in part through use of instructions stored as a physical state in one or more machine-readable storage devices.

An example method 22 of forming a memory device can include features of any of the preceding example methods 12 to 21 of forming a memory device and can include performing functions associated with any features of example memory devices 1 to 10 and example memory devices 11 to 20.

An example method 23 of forming a memory device can comprise forming a line contact on and contacting a memory cell line for an array of memory cells, the memory cell line being an access line or a digit line, using a dry etch and wet etch procedure including: removing a portion of processing layers above a silicon nitride layer positioned on the memory cell line, using a dry etch; removing the silicon nitride layer, exposing a portion of the memory cell line without removing material of the memory cell line, using a selective wet etch; and forming the line contact on and contacting the exposed portion of the memory cell line.

An example method 24 of forming a memory device can include features of example method 23 of forming a memory device and can include depositing an oxide spacer in an opening formed by the dry etch prior to removing the silicon nitride layer using the selective wet etch.

An example method 25 of forming a memory device can include features of any of the preceding example methods 23-24 of forming a memory device and can include removing the portion of processing layers above the silicon nitride layer positioned on the memory cell line to include stopping the dry etch at a top of the silicon nitride layer.

An example method 26 of forming a memory device can include features of any of the preceding example methods 23-25 of forming a memory device and can include removing the silicon nitride layer using the selective wet etch including using a wet phosphoric acid etchant.

An example method 27 of forming a memory device can include features of any of the preceding example methods and can include removing the portion of processing layers above a silicon nitride layer positioned on the memory cell line to include performing a multi-step dry etch.

An example method 28 of forming a memory device can include features of example method 27 of forming a memory device and any of the preceding example methods 23-26 of forming a memory device and can include performing the multi-step dry etch to include removing one or more of the processing layers positioned above a top silicon nitride layer on and contacting an oxide region on the silicon nitride layer positioned on the memory cell line.

An example method 29 of forming a memory device can include features of example method 28 of forming a memory device and any of the preceding example methods 23-27 of forming a memory device and can include performing an additional multi-step dry etch, removing the top silicon nitride layer and the oxide region, and stopping the additional multi-step dry etch on the silicon nitride layer positioned on the memory cell line.

In an example method 30 of forming a memory device, any of the example methods 23 to 29 of forming a memory device may be performed in forming an electronic apparatus further comprising a host processor and a communication bus extending between the host processor and the memory device.

In an example method 31 of forming a memory device, any of the example methods 23 to 30 of forming a memory device may be modified to include operations set forth in any other of example methods 23 to 30 of forming a memory device.

In an example method 32 of forming a memory device, any of the example methods 23 to 31 of forming a memory device may be implemented at least in part through use of instructions stored as a physical state in one or more machine-readable storage devices.

An example method 33 of forming a memory device can include features of any of the preceding example methods 23 to 32 of forming a memory device and can include performing functions associated with any features of example memory devices 1 to 10 and example memory devices 11 to 20.

An example method 34 of forming a memory device can comprise forming a line contact on and contacting an access line for an array of memory cells, using a dry etch and wet etch procedure including: removing a portion of processing layers above a silicon nitride layer positioned on the access line, using a dry etch; removing the silicon nitride layer, exposing a portion of the access line without removing material of the access line, using a selective wet etch; and forming the line contact on and contacting the exposed portion of the access line.

An example method 35 of forming a memory device can include features of example method 34 of forming a memory device and can include depositing an oxide spacer in an opening formed by the dry etch prior to removing the silicon nitride layer using the selective wet etch.

An example method 36 of forming a memory device can include features of any of the preceding example methods 34-35 of forming a memory device and can include removing the portion of processing layers above the silicon nitride layer positioned on the access line to include stopping the dry etch at a top of the silicon nitride layer.

An example method 37 of forming a memory device can include features of any of the preceding example methods 34-36 of forming a memory device and can include removing the silicon nitride layer using the selective wet etch including using a wet phosphoric acid etchant.

An example method 38 of forming a memory device can include features of any of the preceding example methods 34-37 of forming a memory device and can include removing the portion of processing layers above a silicon nitride layer positioned on the access line to include performing a multi-step dry etch.

An example method 39 of forming a memory device can include features of example method 38 of forming a memory device and any of the preceding example methods 34-37 of forming a memory device and can include performing the multi-step dry etch to include removing one or more of the processing layers positioned above a top silicon nitride layer on and contacting an oxide region on the silicon nitride layer positioned on the access line.

An example method 40 of forming a memory device can include features of example method 39 of forming a memory device and any of the preceding example methods 34-38 of forming a memory device and can include performing an additional multi-step dry etch, removing the top silicon nitride layer and the oxide region, and stopping the additional multi-step dry etch on the silicon nitride layer positioned on the access line.

In an example method 41 of forming a memory device, any of the example methods 34 to 40 of forming a memory device may be performed in forming an electronic apparatus further comprising a host processor and a communication bus extending between the host processor and the memory device.

In an example method 42 of forming a memory device, any of the example methods 34 to 41 of forming a memory device may be modified to include operations set forth in any other of example methods 34 to 41 of forming a memory device.

In an example method 43 of forming a memory device, any of the example methods 34 to 42 of forming a memory device may be implemented at least in part through use of instructions stored as a physical state in one or more machine-readable storage devices.

An example method 44 of forming a memory device can include features of any of the preceding example methods 34 to 43 of forming a memory device and can include performing functions associated with any features of example memory devices 1 to 10 and example memory devices 11 to 20.

An example machine-readable storage device storing instructions, that when executed by one or more processors, cause a machine to perform operations, can comprise instructions to perform functions associated with any features of example memory devices 1 to 10 or example memory devices 11 to 20 or perform methods associated with any features of example methods 1 to 44 of forming a memory device.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
access lines to an array of memory cells; and
line contacts to the access lines such that, for each pair of directly adjacent access lines, a first access line of a pair contacts a first line contact of the line contacts, the first line contact being self-aligned such that a minimum distance between the first access line and a second access line of the pair is less than a minimum distance between the second access line and the first line contact.

2. The memory device of claim 1, wherein the line contacts to assigned access lines terminate at a level above a top of the access lines outside horizontal extents of the assigned access lines.

3. The memory device of claim 1, wherein the line contacts include one or more of tungsten, ruthenium, tungsten nitride, titanium, tungsten silicide, polysilicon, or combinations thereof.

4. The memory device of claim 1, wherein the access lines include one or more of polysilicon or a metal.

5. The memory device of claim 1, wherein material of the access lines is selectively resistant to etchants for removing silicon nitride positioned on and contacting the access lines during processing of the line contacts to the access lines.

6. The memory device of claim 5, wherein material of the access lines is selectively resistant to etching by phosphoric acid.

7. A method of forming a memory device, comprising:
forming a line contact on and contacting an access line for an array of memory cells, using a two stage removal procedure of different removal processes including:
removing a portion of processing layers above an insulating protective layer positioned on the access line;
selectively removing the insulating protective layer, exposing a portion of the access line, without removing material of the access line; and
forming the line contact on and contacting the exposed portion of the access line.

8. The method of claim 7, wherein the insulating protective layer includes silicon nitride.

9. The method of claim 7, wherein the processing layers include a hard mask, an underlayer coating, a dielectric anti-reflective coating layer, a carbon layer, a silicon nitride layer, and an oxide layer on the insulating protective layer.

10. The method of claim 7, wherein the method includes:
forming a spacer oxide in an opening formed by removing the portion of processing layers above the insulating protective layer; and
forming the line contact on the spacer oxide during the forming of the line contact on and contacting the exposed portion of the access line.

11. The method of claim 7, wherein removing the portion of processing layers above the insulating protective layer includes stopping the removal on the insulating protective layer.

12. The method of claim 11, wherein stopping the removal on the insulating protective layer includes using an end point detection to stop the removal.

13. The method of claim 7, wherein selectively removing the insulating protective layer without removing the material of the access line includes using one or more chemicals for removal that are resistant by the material of the access line for removal.

14. A method of forming a memory device, the method comprising:
forming a line contact on and contacting an access line for an array of memory cells, using a dry etch and wet etch procedure including:
removing a portion of processing layers above a silicon nitride layer positioned on the access line, using a dry etch;
removing the silicon nitride layer, exposing a portion of the access line without removing material of the access line, using a selective wet etch; and
forming the line contact on and contacting the exposed portion of the access line.

15. The method of claim 14, wherein the method includes depositing an oxide spacer in an opening formed by the dry etch prior to removing the silicon nitride layer using the selective wet etch.

16. The method of claim 14, wherein removing the portion of processing layers above the silicon nitride layer positioned on the access line includes stopping the dry etch at a top of the silicon nitride layer.

17. The method of claim 14, wherein removing the silicon nitride layer using the selective wet etch includes using a wet phosphoric acid etchant.

18. The method of claim 14, wherein removing the portion of processing layers above a silicon nitride layer positioned on the access line includes performing a multi-step dry etch.

19. The method of claim 18, wherein performing the multi-step dry etch includes removing one or more of the processing layers positioned above a top silicon nitride layer on and contacting an oxide region on the silicon nitride layer positioned on the access line.

20. The method of claim 19, wherein the method includes performing an additional multi-step dry etch, removing the top silicon nitride layer and the oxide region, and stopping the additional multi-step dry etch on the silicon nitride layer positioned on the access line.
